(19) United States
(12) Patent Application Publication
(10) Pub. No.: US 2006/0207503 A1
(43) Pub. Date: Sep. 21, 2006

(54) Vaporizer and method of vaporizing a liquid for thin film delivery

(76) Inventors: Paul Meneghini, Haverhill, MA (US); Ali Shajii, Canton, MA (US); Daniel Alexander Smith, North Andover, MA (US); William R. Clark, Hampstead, NH (US)

Correspondence Address: MCDERMOTT WILL & EMERY LLP;ATTN: INTELLECTUAL PROPERTY DEPTARTMENT, 28 STATE STREET, BOSTON, MA, 02109, US

(21) Appl. No.: 11/083,586

(22) Filed: Mar. 18, 2005

(51) Int. Cl. C23C 16/00

(52) U.S. Cl. 118/715

(57) ABSTRACT

A vaporizer including an inlet for liquid and an outlet for gas, a gas valve controlling gas flow to the outlet of the vaporizer, and means for heating liquid flowing between the liquid inlet and the gas valve. The vaporizer also includes means for increasing a heat transfer rate of the liquid flowing between the liquid inlet and the gas valve, and for causing a pressure drop in the liquid so that a pressure of the liquid drops below a vapor transition pressure of the liquid upon reaching the gas valve. The pressure drop occurs under isothermal conditions, and the liquid is vaporized on demand only when the valve is opened. The means for increasing a heat transfer rate and for causing a pressure drop can be a plug of porous media.

### FIELD OF THE DISCLOSURE

The present disclosure relates generally to a vaporizer and a method for vaporizing precursor gases for the formation of thin films.

### BACKGROUND OF THE DISCLOSURE

The manufacture or fabrication of semiconductor devices is very complicated and often requires, for example, the careful synchronization and precisely measured delivery of as many as a dozen gases to a process chamber. Various recipes are used in the manufacturing process, and many discrete processing steps can be required for a semiconductor device, such as cleaning, polishing, oxidizing, masking, etching, doping, and metalization. The steps used, their sequence, and the materials involved all contribute to the making of particular devices.

As device sizes continue to shrink below 90 nm, the semiconductor roadmap suggests that atomic layer deposition, or ALD processes will be required for a variety of applications, such as the deposition of barriers for copper interconnects, and the creation of tungsten nucleation layers. In the ALD process, two or more precursor gases flow over a wafer surface in a process chamber maintained under vacuum. The two or more precursor gases flow in an alternating manner, or pulses, so that the gases can react with the sites or functional groups on the wafer surface. When all of the available sites are saturated from one of the precursor gases (e.g., gas A), the reaction stops and a purge gas is used to purge the excess precursor molecules from the process chamber. The process is repeated, as the next precursor gas (i.e., gas B) flows over the wafer surface. A cycle is defined as one pulse of precursor A, purge, one pulse of precursor B, and purge. This sequence is repeated until the final thickness is reached. These sequential, self-limiting surface reactions result in one monolayer of deposited film per cycle.

The pulses of precursor gases into the processing chamber are normally controlled using on/off-type gas valves which are simply opened for a predetermined period of time to deliver a desired amount of precursor gas from a heated holding container into the processing chamber. Alternatively, a gas mass flow controller, which is a self-contained device consisting of a transducer, gas control valve, and control and signal-processing electronics, is used to deliver repeatable gas flow rate in short time intervals.

In many cases the precursor gases are formed by vaporizing liquids and solids. The current standard technique for vaporizing a liquid is to use a liquid mass flow controller with a separate vaporizer device, or a combined liquid mass flow controller and vaporizer, to deliver vaporized precursor gases to the heated holding container. The liquid is first metered from a source container by the liquid mass flow controller and then vaporized by the vaporizer device before being delivered to the heated holding container. Then the on/off-type gas valve or gas mass flow controller is used to deliver a desired amount of precursor gas from the heated holding container into the processing chamber. A disadvantage of this technique, however, is cost. A liquid mass flow controller and vaporizer device can cost thousands of dollars. In addition, many of the ALD precursers have rather demanding heating requirements, are difficult to accurately flow control due to condensation, and are liable to decompose in an undesirable manner prior to use.

ALD Precursors can vary greatly depending on application. New precursors are still being developed and tested for different substrates and deposition film requirements. Three very common precursors are Al(CH₃)₃ (Al₂O₃ deposition film), HfCl₄ (HfO₂deposition film), and ZrCl₄ (ZrO₂ deposition film). The oxygen precursor for each of these gases is typically H₂O, or O₂ or O₃. Other film types that may be deposited via ALD or CVD techniques include Ni, W, SiO₂, Ta₂O₅, TaN, TiO₂, WN, ZnO, ZrO₂, WCN, Ru, Ir, Pt, RuTiN, Ti, Mo. ZnS, WNₓC_{y}, HfSiO, LaₓCa_{y}MnO₃, CuInS₂, In₂S₃, HfN, TiN, Cu, V₂O₅, and SiN. It should be noted, however, that the present disclosure is not limited to use with any particular precursor or process.

What is still desired is a new and improved vaporizer and a method for vaporizing precursor materials for the formation of thin films, such as in atomic layer deposition (ALD) processes. Preferably, the new and improved vaporizer and method for vaporizing precursor gases will be relatively simple in design and relatively inexpensive in comparison to existing methods and devices for vaporizing precursor materials. In addition, the new and improved vaporizer and method for vaporizing will preferably provide vapor on demand at the point where the vapor is actually metered, as opposed to creating the vapor and storing the vapor prior to use.

### SUMMARY OF THE DISCLOSURE

The present disclosure provides a vaporizer including an inlet for receiving liquid and an outlet for delivering gas, a gas valve controlling gas flow to the outlet of the vaporizer, and means for heating the liquid flowing between the liquid inlet and the gas valve. The vaporizer also includes means for increasing the heat transfer rate to liquid flowing between the liquid inlet and the gas valve, and for causing a pressure drop to liquid flowing between the liquid inlet and the gas valve, so that a pressure of the liquid drops below a vapor transition pressure of the liquid upon reaching the gas valve.

According to one aspect of the present disclosure, the means for causing a pressure drop between the fluid inlet and the gas valve and for increasing the heat transfer rate to the liquid flowing between the fluid inlet and the gas valve comprises a porous plug connecting the fluid inlet to the gas valve.

According to another aspect of the present disclosure, the vaporizer is incorporated into a system for delivering pulsed mass flow of precursor gases into semiconductor processing chambers, wherein the system actually measures the amount of material (mass) flowing into the process chamber and delivers highly repeatable and precise quantities of gaseous mass.

Among other aspects and advantages, the present disclosure provides a new and improved vaporizer, and a method for vaporizing precursor gases for the formation of thin films, such as in atomic layer deposition (ALD) processes as well as other chemical vapor deposition (CVD) processes. The new and improved vaporizer and method for vaporizing precursor gases is relatively simple in design and is relatively inexpensive. In addition, the new and improved vaporizer allows liquid to be vaporized on demand, when metered (i.e., only when the gas valve is opened).

Additional aspects and advantages of the present disclosure will become readily apparent to those skilled in this art from the following detailed description, wherein an exemplary embodiment of the present disclosure is shown and described, simply by way of illustration. As will be realized, the present disclosure is capable of other and different embodiments and its several details are capable of modifications in various obvious respects, all without departing from the disclosure. Accordingly, the drawings and description are to be regarded as illustrative in nature, and not as restrictive.

### BRIEF DESCRIPTION OF THE DRAWINGS

Reference is made to the attached drawings, wherein elements having the same reference characters represent like elements throughout, and wherein:

FIG. 1 is a schematic illustration of an exemplary embodiment of a vaporizer constructed in accordance with the present disclosure;

FIG. 2 is a schematic illustration of an exemplary embodiment of an atomic layer deposition system including the vaporizer of FIG. 1;

FIG. 3 is a schematic illustration of an exemplary embodiment of a pulsed mass flow delivery system including the vaporizer of FIG. 1;

FIG. 4 is a flow chart illustrating an exemplary embodiment of a method for delivering pulsed mass flows, wherein the method can be used to operate the pulsed mass flow delivery system of FIG. 3;

FIG. 5 is a side elevation view of an exemplary embodiment of a vaporizer constructed in accordance with the present disclosure;

FIG. 6 is an end elevation view of the vaporizer of FIG. 5;

FIG. 7 is a sectional view of the vaporizer taken along line 7--7 of FIG. 5;

FIG. 8 is a sectional view of the vaporizer taken along line 8--8 of FIG. 6;

FIG. 9 is an enlarged sectional view of a portion of the vaporizer of FIG. 5, wherein liquid flow through an inlet and into a porous plug of the vaporizer is illustrated, and gas flow out of the porous plug, through a valve assembly and an outlet of the vaporizer is illustrated; and

FIG. 10 is a graph of pressure versus porous plug length for water passing through four porous plug assemblies of varying pore size.

### DETAILED DESCRIPTION OF EXEMPLARY EMBODIMENTS

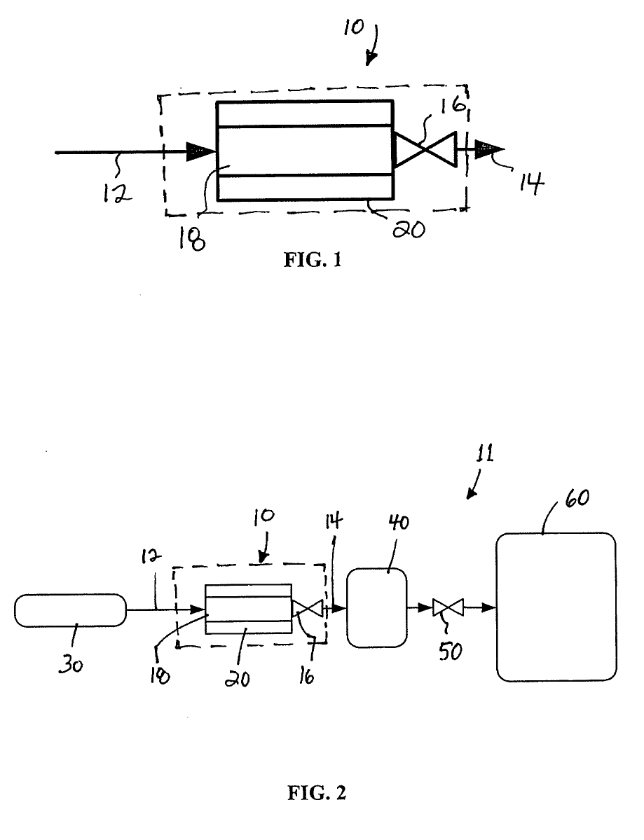

Referring first to FIGS. 1 and 2, the present disclosure provides a new and improved vaporizer 10, and a method for vaporizing precursor gases for the formation of thin films, such as in atomic layer deposition (ALD) processes, or other chemical vapor deposition (CVD) processes. Among other aspects and advantages, the new and improved vaporizer and method for vaporizing precursor gases, according to the present disclosure, is relatively simple in design and is relatively inexpensive.

As shown in FIGS. 1 and 2, the vaporizer 10 includes an inlet 12 for liquid, an outlet 14 for gas, and a gas valve 16 controlling gas flow to the outlet 14. The vaporizer 10 also includes means 18 for causing a smooth pressure drop between the liquid inlet 12 and the gas valve 16 and for increasing the heat transfer rate to the liquid flowing between the liquid inlet and the gas valve. The vaporizer 10 additionally includes means 20 for heating the liquid flowing between the liquid inlet 12 and the gas valve 16 so that the temperature remains constant, or increases, while the pressure drops below the vapor curve. The pressure of the liquid entering the liquid inlet is decreased sufficiently and quickly enough by the pressure drop means 18 to cause the pressure of the liquid to drop below a vapor transition pressure and become vaporized upon reaching the gas valve. Although not shown, the vaporizer 10 may also include a sensor for monitoring the temperature of the pressure drop means 18, and controller circuitry for controlling the heating means 20 based on the temperature.

The vapor pressure is the pressure (if the vapor is mixed with other gases, the partial pressure) of a vapor. At any given temperature, for a particular substance, there is a pressure at which the vapor of that substance is in equilibrium with its liquid or solid forms. This is the saturated vapor pressure of that substance at that temperature. The term vapor pressure is often understood to mean saturated vapor pressure. When the pressure of any liquid equals its saturated vapor pressure, the liquid is partially vaporized: liquid and vapor are in equilibrium. Given a constant temperature, if the pressure is reduced, the equilibrium is changed the substance's gas phase: The liquid eventually gets totally vaporized.

According to one exemplary embodiment of the present disclosure, the means for causing a pressure drop and for increasing the heat transfer rate comprises a porous media plug 18. It is important to note that the pressure at the exit of the valve must be below the vapor pressure of the liquid. Otherwise, liquid will exit the porous media and the gas valve may not be able to close. The high heat transfer rate is necessary to ensure constant temperature because the vaporizing liquid creates a heat sink. If the local temperature of the porous media plug 18 drops, the local saturated vapor pressure will drop with it, sometimes below the pressure at the exit. Then there won't be any vaporization in the porous media plug 18.

Suitable porous media is available, for example, from Mott Corporation of Farmington, Conn. (http://www.mottcorp.com). According to one exemplary embodiment, the porous media is made from sintered metal. The sintered metal can be formed from metal powder having a pre-sintered mean particle size of less than 20 microns. According to another embodiment, the mean particle size of the sintered elements is less than 10 microns and the sintered metal has a density of at least 5 g/cc. The metal used to make the plug 18 is selected from, but not limited to, a group consisting of stainless steel, nickel and nickel alloys, and titanium, to meet special requirements, such as greater temperature and corrosion resistance. In particular, the metals and alloys include, but are not limited to, Stainless Steel 316L, 304L, 310, 347 and 430, Hastelloy C-276, C-22, X, N, B and B2, Inconel 600, 625 and 690, Nickel 200 and Monelo® 400 (70 Ni-30 Cu), Titanium, and Alloy 20.

According to a further exemplary embodiment of the present disclosure, the porous media plug 18 is made of Stainless Steel 316L and is adapted to provide a flow rate of 10 sccm (Standard Cubic Centimeters per Minute) of nitrogen at a pressure of 30 psig (gage pressure using atmospheric pressure as a zero reference). According to other exemplary embodiments, the porous media plug 18 is made of: Stainless Steel 316L and is adapted to provide a flow rate of 50 sccm of N₂ at 30 psig; Stainless Steel 316L and is adapted to provide a flow rate of 250 sccm of N₂ at 30 psig; or Nickel 200 and is adapted to provide a flow rate of 50 sccm of N₂ at 30 psig. According to one exemplary embodiment of the present disclosure, the porous media plug 18 is cylindrical and elongated and may comprise a single, elongated piece of porous media, or may comprise individual inserts stacked to form an elongated assembly of porous media.

The porous media plug 18 may also be assembled of an inner cylinder coaxially receive in an outer sleeve, and the inner cylinder and the outer sleeve may be comprised of different porous media. Such an assembly will provide parallel flows of vapor.

The porosity or pore size of the porous media plug 18 controls the pressure drop. According to one exemplary embodiment, the porous media plug 18 comprises a one piece insert made by sintering one piece from two different frit sizes. Each frit size will correspond to a different pore size, or porosity.

The porous media plug 18 may comprise materials other than metals, such as quartz, ceramic (sapphire, alumina, aluminum nitride, etc.), and polymeric materials, including Teflon, PFA, PTFA, etc.

The means 18 for causing a pressure drop and for increasing the heat transfer rate may alternatively take other forms, such as, but not limited to, a long, thin, straight capillary tube, a long, thin, coiled capillary tube, a bundle of thin capillary tubes, or a laminar flow element.

As shown in FIG. 2, the vaporizer 10 of FIG. 1 can be used to provide vaporized gas precursors to a process chamber 60 for the formation of thin films, such as in atomic layer deposition (ALD) processes and other chemical vapor deposition (CVD) processes. An exemplary embodiment of an atomic layer deposition system 11 including the vaporizer 10 of FIG. 1 is shown in FIG. 2, and fuirther includes a source 30 of liquid precursor, a delivery chamber 40, and a gas valve 50 connecting the delivery chamber 40 to the process chamber 60. As shown, the inlet 12 of the vaporizer 10 is connected to the liquid source 30, while the outlet 14 of the vaporizer is connected to the delivery chamber 40. The vaporizer 10 is used to vaporize liquid precursor from the liquid source 30 and deliver the vaporized liquid, or precursor gas to the delivery chamber 40. Although not shown, the delivery chamber 40 may be heated. The gas valve 50 can then be opened and closed to deliver precursor gas from the delivery chamber 40 to the process chamber 60, as desired to create a thin film in the process chamber.

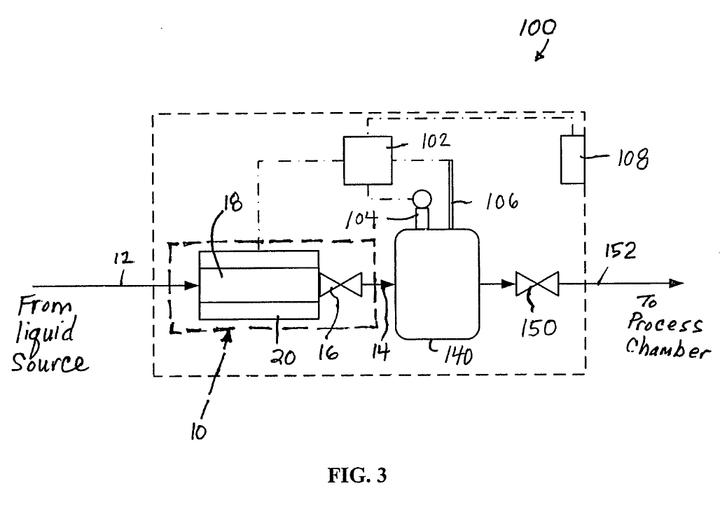

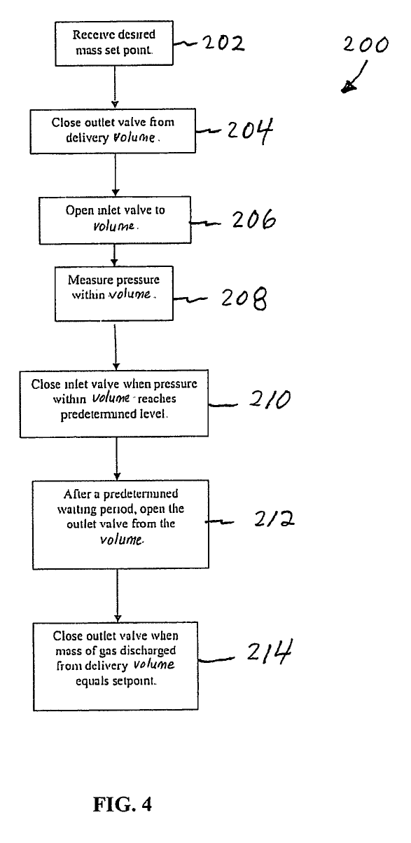

Referring to FIG. 3, an exemplary embodiment of a mass flow delivery system 100 constructed in accordance with the present disclosure is shown, and includes the vaporizer 10 of FIG. 1. FIG. 4 shows an exemplary embodiment of a method 200 for delivering mass flow, wherein the method can be used to operate the pulsed mass flow delivery system of FIG. 3. The system 100 and the method 200 are particularly intended for delivering contaminant-free, precisely metered quantities of process gases to semiconductor process chambers, such as a process chamber of an ALD or CVD apparatus. The mass flow delivery system 100 and the method 200 actually measure the amount of material (mass) flowing into the process chamber. In addition, the system 100 and the method 200 provide highly repeatable and precise quantities of gaseous mass for use in semiconductor manufacturing processes, such as ALD or CVD processes.

Referring to FIG. 3, the mass flow delivery system 100 includes a holding volume 140 connected to the vaporizer 10, and a valve 150 controlling mass flow out of the holding volume 140. According to one exemplary embodiment of the present disclosure, the valve 150 comprise an on/off type valve having a relatively very fast response time of about 1 to 5 milliseconds. The mass flow delivery system 100 also has a pressure transducer 104 for providing measurements of pressure within the holding volume 140 and a temperature sensor 106 for providing measurements of temperature on or within the holding volume 140. The pressure transducer 104 also has a relatively very fast response time of about 1 to 5 milliseconds. According to one exemplary embodiment of the present disclosure, the temperature sensor 106 is in contact with, and provides measurements of the temperature of, a wall of the holding volume 140. Examples of a suitable pressure transducer 104 for use with the delivery system 100 of the present disclosure are Baratrono brand pressure transducers available from the assignee of the present disclosure, MKS Instruments of Wilmington, Mass. (http://www.mksinst.com). A suitable valve 150 is, for example, a diaphragm valve for atomic layer deposition which is available from Swagelok Company of Solon, Ohio (www.swagelok.com).

An input/output device 108 of the mass flow delivery system 100 receives a desired mass flow (either directly from a human operator or indirectly through a wafer processing computer controller), and a computer controller (i.e., computer processing unit or “CPU”) 102 is connected to the pressure transducer 104, the temperature sensor 106, the outlet valve 150 and the input/output device 108. The input/output device 108 can also be used to input other processing instructions, and can be used to provide an indication (either directly to a human operator or indirectly through a wafer processing computer controller) of the mass delivered by the system 100. The input/output device 108 may comprise a personal computer with a keyboard, mouse, and monitor, for example.

According to one exemplary embodiment of the disclosure, the controller 102 of the mass flow delivery systems 100 of FIG. 3 carries out the method 200 of FIG. 4. Referring to FIGS. 3 and 4, the controller 102 is programmed to receive the desired mass flow (i.e., set point) through the input/output device 108, as shown at 202 of FIG. 4, close the outlet valve 150, as shown at 204 of FIG. 4, open the valve 16 of the vaporizer 10, as shown at 206 of FIG. 4, measure pressure within the holding volume 140 using the pressure transducer 104, as shown at 208 of FIG. 4, and close the inlet valve 16 when pressure within the holding volume 140 reaches a predetermined level, as shown at 210 of FIG. 4. The predetermined level of pressure is user defined and can be provided through the input/output device 108. The predetermined level of pressure can comprise, for example, 200 torr.

After a predetermined waiting period, wherein the gas inside the holding volume 140 can approach a state of equilibrium, the outlet valve 150 is opened to discharge a mass of gas from the holding volume 140, as shown at 212 of FIG. 4. The predetermined waiting period is user defined and can be provided through the input/output device 108. The predetermined waiting period can comprise, for example, 3 seconds. The outlet valve 150 is then closed when the mass of gas discharged equals the user defined desired mass flow, as shown at 214 of FIG. 4. The outlet valve 150 is opened for only a very short period (e.g., 100 to 500 milliseconds). The controller 102 then provides the mass of gas discharged to the input/output device 108.

Alternative modes of operation are possible. For example, in some instances it may be desirable to fill the holding volume 140 to a given pressure, such that multiple doses of the gas within the holding volume may be delivered through the outlet valve, before the holding volume is refilled. In other instances it may be desirable to deliver a dose of gas over a much longer period of time, wherein the outlet valve will be opened for longer periods (e.g. 0.5 to 30 seconds). In addition, the operational lives of the valves may be prolonged by using multiple valves at the inlet or outlet. Only one of the two valves would be pulsed at a time, and upon failure of that first valve, the second valve would take over. To accommodate failure of a value in either open or closed mode, four values would be needed: two in series, and these in parallel with another pair. U.S. patent application Ser. No. 11/015,465, filed on Dec. 17, 2004, which is entitled “Pulsed Mass Flow Deliver System and Method” and is assigned to the assignee of the present disclosure, discloses such an arrangement and is incorporated herein by reference.

For high pressure applications, the temperature of the gas within the holding volume 140 of the system 100 can be measured using the temperature probe 106. For low pressure applications and fast temperature transients, however, using a probe to measure the temperature may not be fast enough for accurate readings. In the case of low pressure applications and fast temperature transients a real-time physical model that estimates gas temperature is used, as described below.

For some precursor materials, it may be difficult to achieve an adequate vapor pressure of the material simply by heating it. For example, some materials may decompose excessively on heating to an adequate vapor pressure for delivery, reducing the effectiveness of the deposition process. In other cases the temperature required to vaporize sufficiently may be undesirably high. In such cases, the precursor material may be dissolved in an appropriate solvent, and then vaporized. Examples of solvent materials include various alcohols, ethers, acetone, and oils. Either organic or inorganic solvents may be suitable, depending on the particular application. Supercritical CO₂ can act as an effective solvent for various materials.

The total mass m in the holding volume 140 based on the ideal gas law is:
m=ρV=(P/RT)V (1)

where ρ equals density, V equals volume, P equals absolute pressure, T equals absolute temperature, and R is equal to the gas constant.

The density dynamics within the holding volume 140 is:
dρ/dt=−(Qₒᵤₜρ_{STP}/V) (2)

Where Qₒᵤₜ is the flow out of the holding volume 140, and ρ_{STP} is the gas density under standard temperature and pressure (STP) conditions.

The Temperature dynamics within the holding volume 140 is:
dT/dt=(ρ_{STP}/ρV)Qₒᵤₜ(γ−1)T+(Nuκ/l)(A_{W}/VC_{ν}ρ)(T_{w}−T) (3)

Where γ is the ratio of specific heats, Nu is Nusslets number, κ is the thermal conductivity of the gas, C_{ν} is the specific heat under constant volume, l is the characteristic length of the delivery chamber, and T_{w} is the temperature of the wall of the holding volume 140 as provided by the temperature probe 106.

The outlet flow Qₒᵤₜ can be estimated as follows:
Qₒᵤₜ=−(V/ρ_{STP})[(1/RT)(dρ/dt)−(P/RT²)(dT/dt)] (4)

To compute the total mass delivered Δm from the holding volume 140, equation (4) is substituted for Qₒᵤₜ in equation (3) to calculate the gas temperature T(t), at time=t, within the holding volume 140, as opposed to using the temperature probe 106 in FIG. 3. The pressure transducer 104 provides the pressure P(t), at time=t, within the holding volume 140.

The total mass delivered Δm from the holding volume 140 between time t₀ and time t* is:
Δm=m(t₀)−m(t*)=V/R[(P(t₀)/T(t₀))−(P(t*)/T(t*))] (5)

Among other aspects and advantages, the mass flow delivery system and method, such as the exemplary embodiments shown in FIGS. 3 and 4, actually measures the amount of material (mass) flowing into the process chamber. In addition, the system and method provide highly repeatable and precise quantities of gaseous mass for use in semiconductor manufacturing processes, such as atomic layer deposition (ALD) processes.

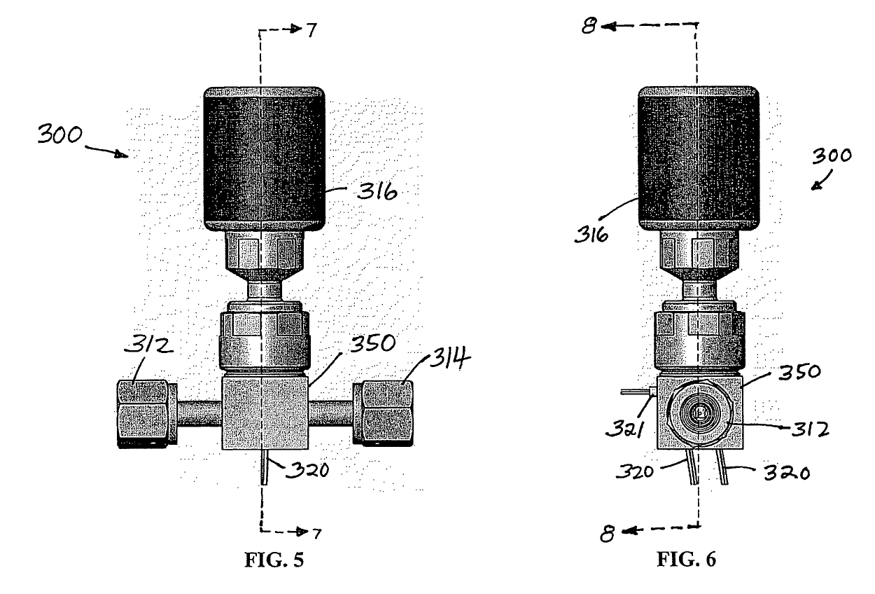

FIGS. 5-9 show another exemplary embodiment of a vaporizer 300 constructed in accordance with the present disclosure, wherein the vaporizer 300 includes a valve body 350 containing a porous plug assembly 318. The vaporizer 300 is similar to the vaporizer 10 of FIG. 1 such that similar elements have the same reference numeral preceded by a “3”.

The vaporizer 300 of FIGS. 5-9 utilizes a diaphragm valve 316 for atomic layer deposition. A suitable diaphragm valve 316 for atomic layer deposition, including the valve body 350, is available, for example, from Swagelok Company of Solon, Ohio (www.swagelok.com).

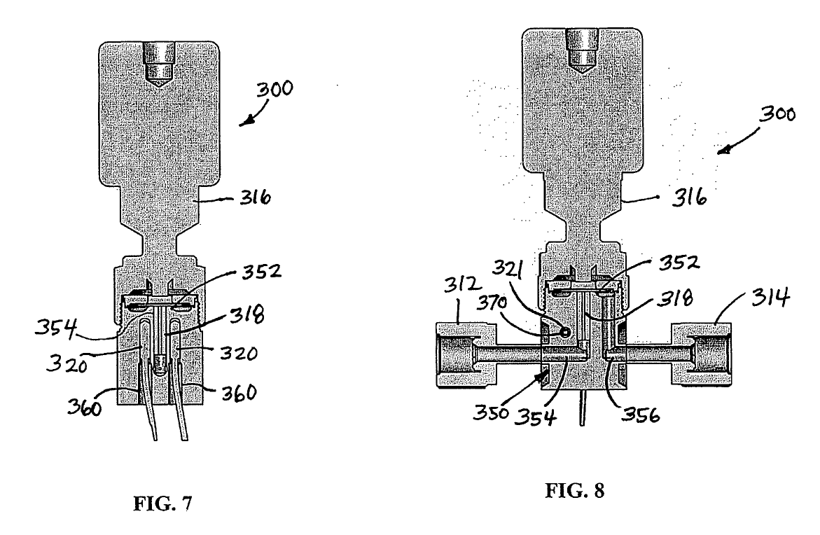

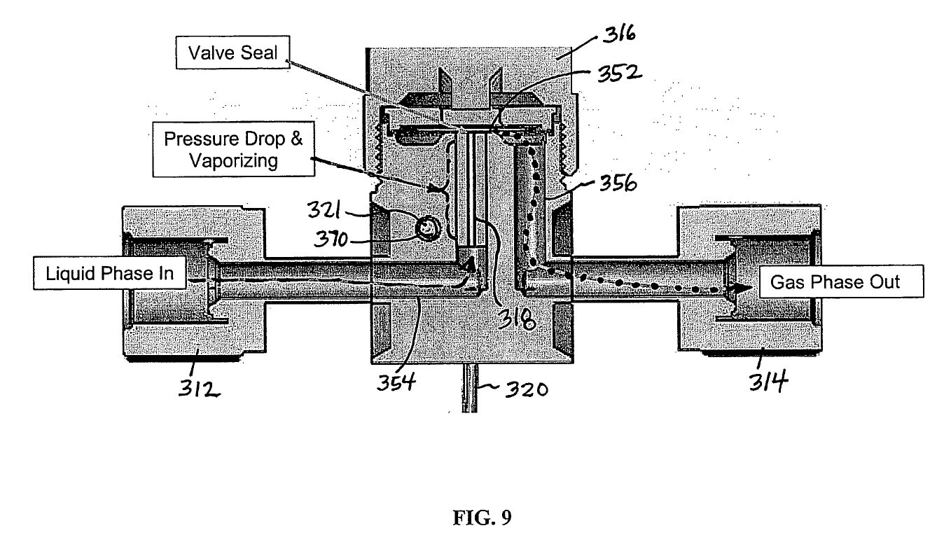

In the exemplary embodiment shown in FIGS. 5-9, the valve body 350 includes female connectors at the inlet 312 and at the outlet 314. As shown best in FIGS. 7-9, the valve body 350 defines a valve seat 352, an inlet passageway 354 extending from the inlet 312 to the valve seat 352, and an outlet passageway 356 extending from the valve seat 352 to the outlet 314. As shown best in FIG. 7, the valve body 350 also defines bores 360 for receiving heaters 320. As shown best in FIGS. 8-9, the valve body 350 also defines a bore 370 for receiving a temperature monitor 321.

The porous plug assembly 318 is positioned in the inlet passageway 354 of the valve body 350. In the exemplary embodiment shown, the porous plug assembly 318 is cylindrical and elongated and comprises a single, elongated piece of porous media received in a solid metal sleeve. Alternatively, the porous plug assembly may comprise individual inserts stacked to form the elongated assembly, and the inserts may be comprised of different porous media (i.e., provide different flow rates at the same pressures).

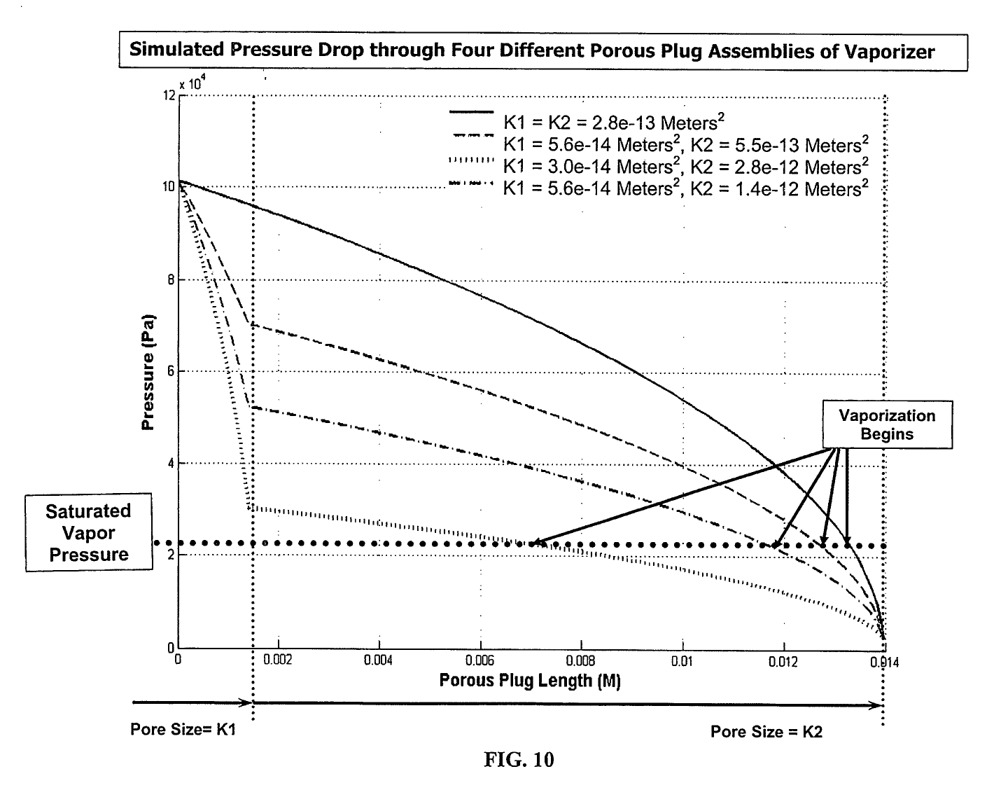

FIG. 10 is a graph of pressure versus porous plug length for a hypothetical liquid at a constant temperature passing through four porous plug assemblies of varying pore sizes K1 and K2. In the examples shown, the assemblies have an overall length of about 0.014 meters, and the assemblies also have a first portion with a pore size of K1 and a second portion with a pore size of K2. One of the porous plug assemblies comprises K1=K2=2.8e−13 Meters². Another assembly comprises K1=5.6e−14 Meters² and K2=5.5e−13 Meters². An additional assembly comprises K1=3.0e−14 Meters² and K2=2.8e−12 Meters². A further assembly comprises K1=5.6e−14 Meters² and K2=1.4e−12 Meters². The graph illustrates that each of the porous plug assemblies causes the liquid to vaporize before passing through the assemblies.

The exemplary embodiments described in this specification have been presented by way of illustration rather than limitation, and various modifications, combinations and substitutions may be effected by those skilled in the art without departure either in spirit or scope from this disclosure in its broader aspects and as set forth in the appended claims.

What is claimed is:

1. A vaporizer comprising:
an inlet for liquid;
an outlet for gas;
a gas valve controlling gas flow to the gas outlet;
means for heating liquid flowing between the liquid inlet and the gas valve; and
means for causing a pressure drop in the liquid flowing between the liquid inlet and the gas valve and for increasing a heat transfer rate of liquid flowing between the liquid inlet and the gas valve, so that a pressure of the liquid drops below the vapor transition pressure of the liquid upon reaching the gas valve.

2. A vaporizer according to claim 1, wherein the means for causing a pressure drop and for increasing the heat transfer rate comprises a plug of porous media.

3. A vaporizer according to claim 2, wherein the porous media comprises sintered metal.

4. A vaporizer according to claim 3, wherein the sintered metal is formed from metal powder having a pre-sintered mean particle size of less than 20 microns.

5. A vaporizer according to claim 4, wherein the mean particle size of the sintered elements are less than 10 microns.

6. A vaporizer according to claim 3, wherein the sintered metal has a density of at least 5 g/cc.

7. A vaporizer according to claim 3, wherein the metal is selected from the group consisting of stainless steel, nickel and nickel alloys, and titanium.

8. A vaporizer according to claim 3, wherein the porous media plug has a first portion with a first pore size and a second portion with second pore size, in series.

9. A vaporizer according to claim 3, wherein the porous media plug is cylindrical and elongated and comprises a single, elongated piece of porous media.

10. A vaporizer according to claim 3, wherein the porous media plug comprises individual inserts stacked to form an elongated assembly of porous media.

11. A vaporizer according to claim 3, wherein the porous media plug is cylindrical and elongated and comprises an inner cylinder coaxially receive in an outer sleeve, and the inner cylinder and the outer sleeve are comprised of different porous media.

12. A vaporizer according to claim 3, wherein the valve includes a valve body and the valve body has a valve seat, an inlet passageway extending from the inlet of the vaporizer to the valve seat, and an outlet passageway extending from the valve seat to the outlet of the vaporizer, and wherein the porous plug is positioned in the inlet passageway.

13. A vaporizer according to claim 1, wherein the means for heating comprise electric heater coils and the vaporizer fuirther includes a temperature sensor.

14. A vaporizer according to claim 1, wherein the valve comprises a diaphragm valve.

15. An atomic layer deposition system including a vaporizer according to claim 1, and further comprising:
a holding volume, wherein the inlet of the vaporizer is connectable to a source of liquid precursor while the outlet of the vaporizer is connected to the holding volume; and
a gas valve for connecting the holding volume to a process chamber.

16. A system according to claim 15, further comprising a process chamber connected to the holding volume through the gas valve.

17. A system for delivering a desired mass of gas including a vaporizer according to claim 1, and further comprising:
a holding volume connected to the outlet of the vaporizer;
an outlet valve controlling gas flow out of the holding volume;
a pressure transducer providing measurements of pressure within the holding volume;
an input device for providing a desired mass of gas to be delivered from the system;
a controller connected to the valves, the pressure transducer and the input device and programmed to,
receive the desired mass of gas through the input device,
close the outlet valve;
open the valve of the vaporizer;
receive holding volume pressure measurements from the pressure transducer;
close the valve of the vaporizer when pressure within the holding volume reaches a predetermined level;
wait a predetermined waiting period to allow the gas inside the holding volume to approach a state of equilibrium;
open the outlet valve at time=t₀; and
close the outlet valve at time=t* when the mass of gas discharged equals the desired mass.

18. A system according to claim 17, wherein the predetermined waiting period comprises 3 seconds.

19. A system according to claim 17, wherein t*=100 to 500 milliseconds.

20. A system according to claim 17, wherein t*=0.5 to 30 seconds.

21. A system according to claim 17, wherein the predetermined level of pressure within the holding volume allows a predetermined numbers of doses of the gas within the holding volume to be delivered through the outlet valve before the holding volume is required to be refilled.

22. A system according to claim 17, wherein liquid is dissolved in an appropriate solvent before being delivered to the inlet of the vaporizer.

23. A system according to claim 17, further comprising a process chamber connected to the holding volume through the outlet valve.

24. A method for vaporizing a liquid comprising:
receiving liquid through an inlet;
connecting a gas valve to the inlet;
heating the liquid flowing between the liquid inlet and the gas valve such that a temperature of the liquid is prevented from dropping even as a pressure of the liquid is dropped;
increasing a heat transfer rate of the liquid flowing between the liquid inlet and the gas valve; and
applying a pressure drop to the liquid flowing between the liquid inlet and the gas valve so that a pressure of the liquid drops below a vapor transition pressure of the liquid upon reaching the gas valve.

25. A method according to claim 24, wherein a plug of porous media is used to apply a pressure drop to the liquid flowing between the liquid inlet and the gas valve and to increase the heat transfer rate of the liquid.

26. A method according to claim 24, wherein liquid is dissolved in an appropriate solvent before being received through the inlet.
